(19) United States
(12) Patent Application Publication
(10) Pub. No.: US 2026/0005149 A1
(43) Pub. Date: Jan. 1, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Hung-En HSU, Taipei City (TW); Ping-Tai CHEN, Taipei City (TW); Ming-Wei PENG, Taoyuan City (TW); Kuo-Ching HSU, Taipei (TW)

(73) Assignee: Taiwan Semiconductor Manufacturing Company, Ltd., Hsinchu (TW)

(21) Appl. No.: 18/756,680

(22) Filed: Jun. 27, 2024

(51) Int. Cl. H01L 23/538; H01L 21/48; H01L 23/00; H01L 23/31; H01L 25/00; H01L 25/10

(52) U.S. Cl. CPC H01L 23/5383; H01L 21/4857; H01L 24/16; H01L 24/32; H01L 24/73; H01L 23/3107; H01L 25/105; H01L 25/50; H01L 2224/16227; H01L 2224/26165; H01L 2224/26175; H01L 2224/32225; H01L 2224/73204

(57) ABSTRACT

A method for fabricating a package structure is provided. The method includes forming a first patterned photoresist layer over a first surface of a substrate. The method includes forming a plurality of first connector structures in openings of the first patterned photoresist layer. The method includes removing the first patterned photoresist layer. The method includes forming a solder mask layer over the first connector structures. The method includes performing a surface treatment process to the first connector structures. The method also includes bonding a package component to the substrate via the first connector structures.

### BACKGROUND

The semiconductor industry has experienced rapid growth due to ongoing improvements in the integration density of a variety of electronic components (e.g., transistors, diodes, resistors, capacitors, etc.). For the most part, improvements in integration density have resulted from iterative reductions of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

Although existing package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1Q illustrates cross-sectional views of intermediate steps during a process for fabricating a package structure in accordance with some embodiments.

FIG. 2 illustrates a partial enlarged view of the package structure in accordance with some embodiments.

FIG. 3 illustrates a cross-sectional view of the package structure in accordance with some embodiments.

FIG. 4 illustrates a cross-sectional view of the package structure in accordance with some embodiments.

FIG. 5 illustrates a cross-sectional view of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and method for fabricating the same are provided. The package structure includes a plurality of connector structure exposed from the solder mask layer. In some embodiments, the connector structure are formed prior to depositing the solder mask layer and include metallic features. As a result, the pitch between the connector structures may be narrowed down without degrading the reliability of the package structure. The fine pitch may help to increase the integrated density of the package structure. In addition, the sidewall of the connector structures may be vertical, that is for example, parallel to the normal direction of the substrate. Accordingly, the stress of the connector structures may be relieved, providing a larger process window. Furthermore, the connector structures may include a dummy connector structure which serve as a barrier for positioning the package components, thereby increasing the yield of the package structure.

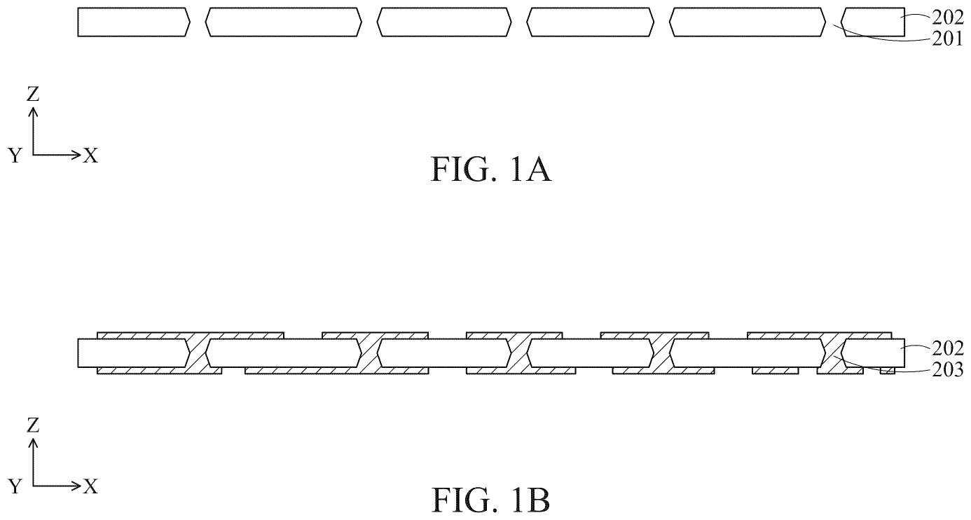

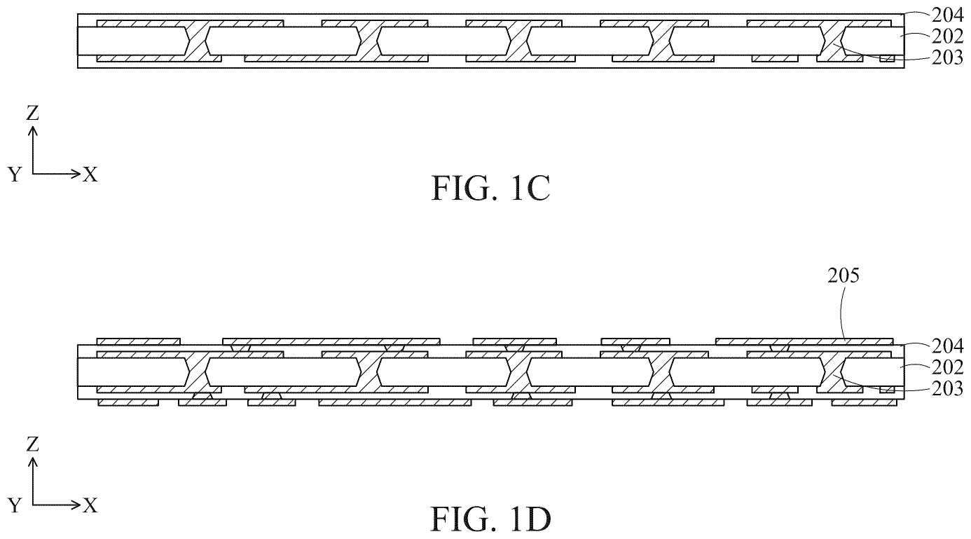

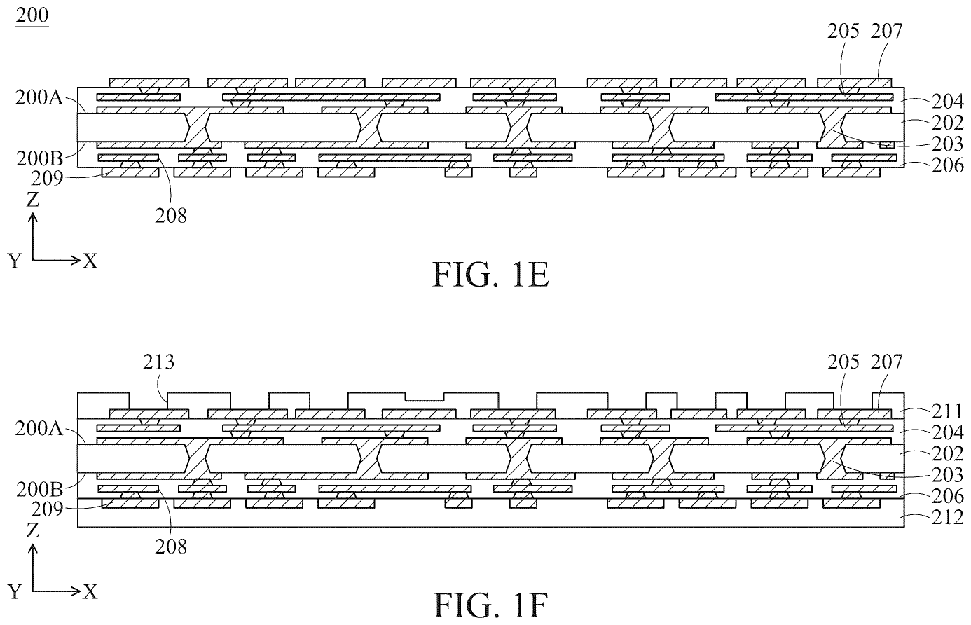

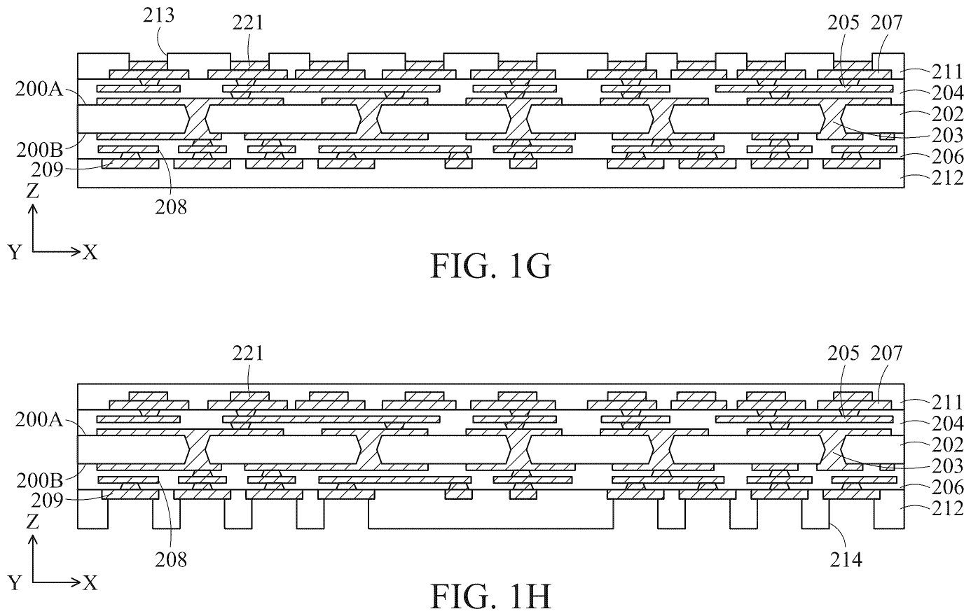

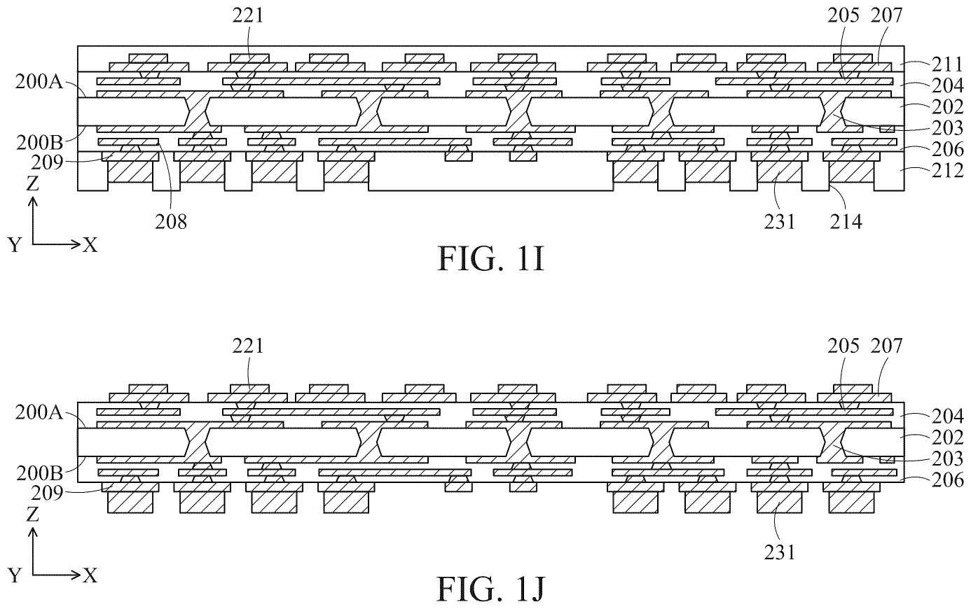

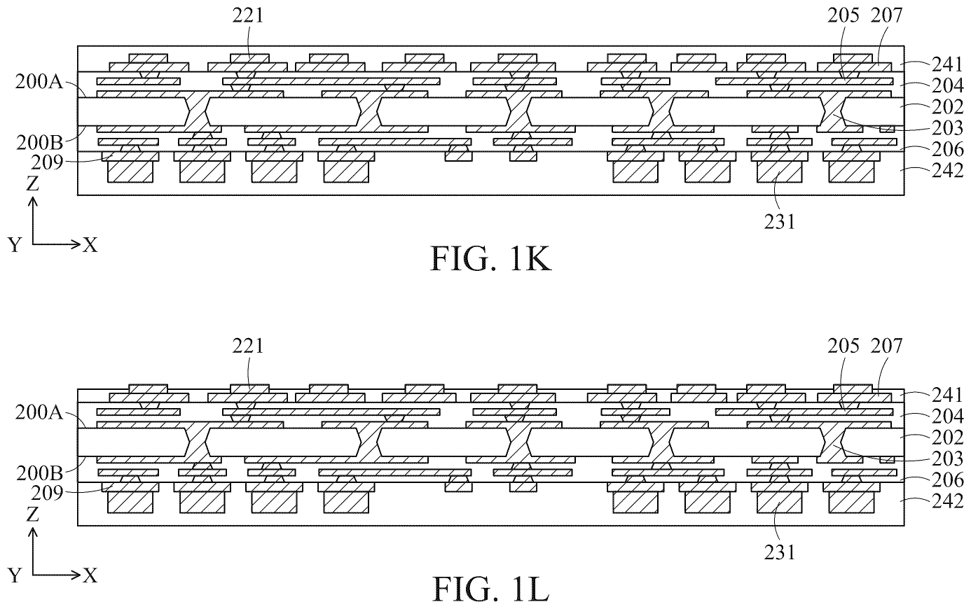

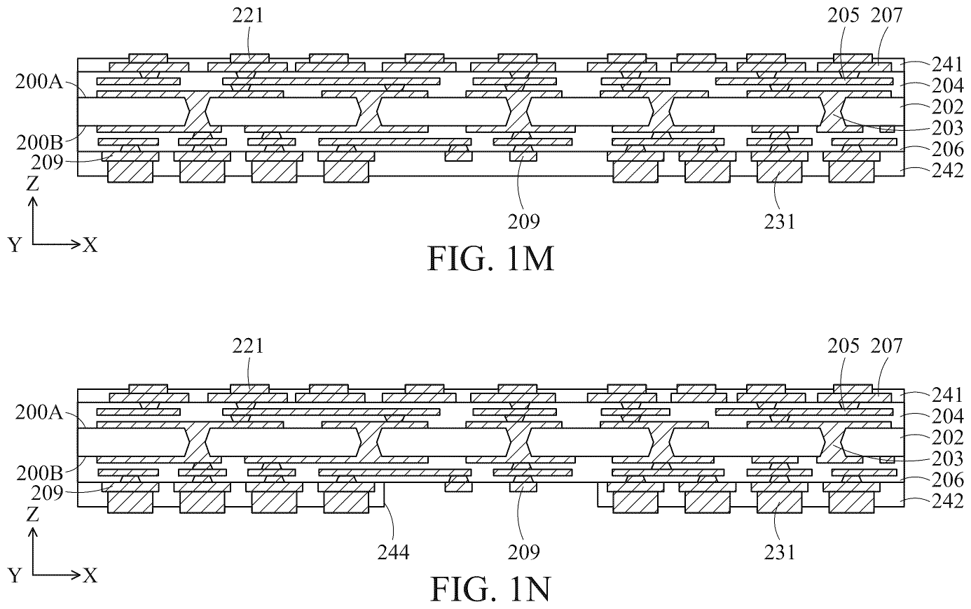

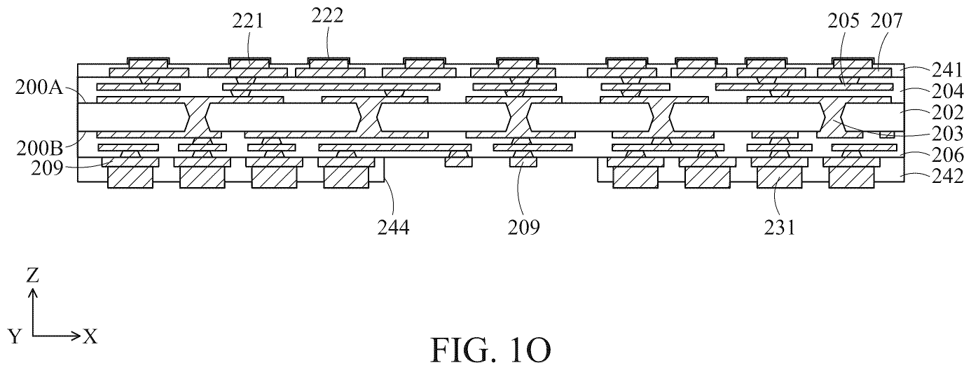

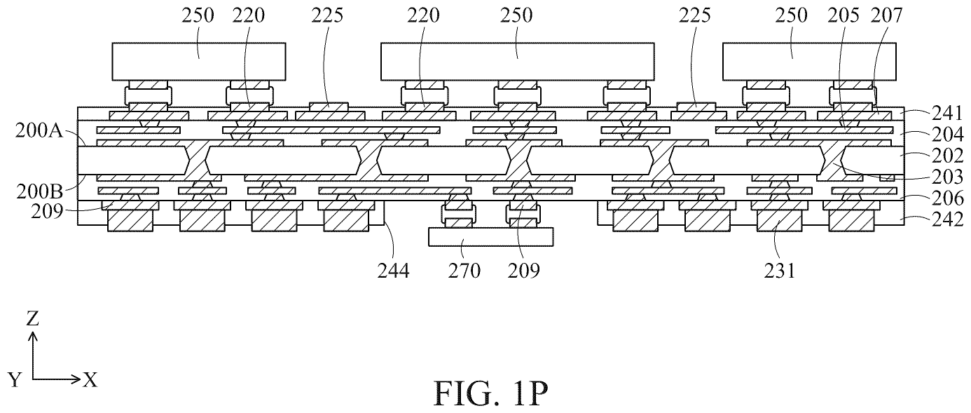

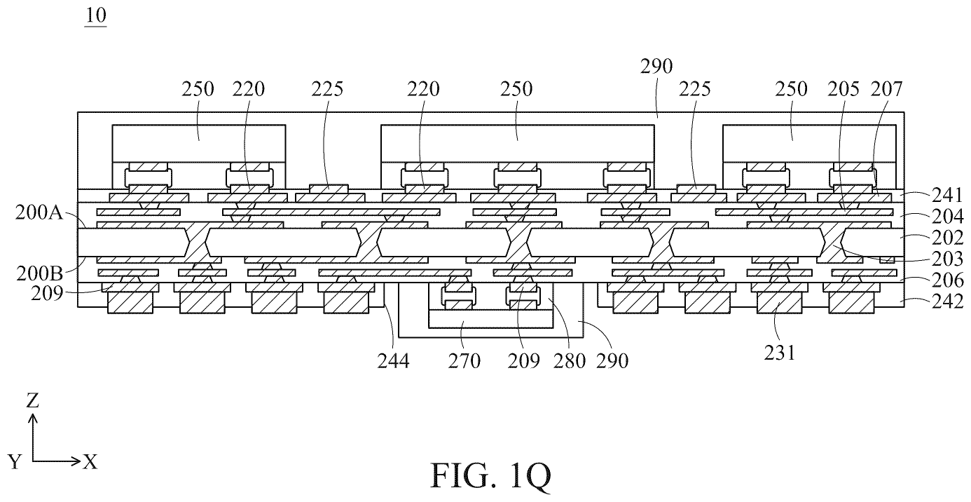

FIGS. 1A through 1Q illustrates cross-sectional views of intermediate steps during a process for fabricating a package structure 10 in accordance with some embodiments. As shown in FIG. 1A, the substrate 200 is based on an insulating core 202 such as a fiberglass reinforced resin core. One example core material is fiberglass resin. Alternatives for the core material include bismaleimide-triazine (BT) resin, or alternatively, other PCB materials or films. Build up films or other laminates may be used for the substrate 200. In some embodiments, a plurality of through holes 201 are formed in the insulating core 202.

In some alternative embodiments, the substrate 200 includes or is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the substrate 200 is a semiconductor-on-insulator (SOI) substrate. Generally, an SOI substrate includes a layer of a semiconductor material such as epitaxial silicon, germanium, silicon germanium, SOI, SGOI, or combinations thereof.

Next, as shown in FIG. 1B, a plurality of conductive features 203 are formed in and extend through the through holes 201. In some embodiments, the conductive features 203 include conductive material and extend on opposite surfaces of the insulating core 202. As an example to form the conductive features 203, a seed layer is formed in the through holes 201 extending through the insulating core 202. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the conductive features 203. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the conductive features 203. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

Then, as shown in FIG. 1C, a dielectric layer 204 is formed over the conductive features 203 and on the upper side of the insulating core 202. In some embodiments, the dielectric layer 204 completely covers the underlying conductive features 203 for insulation, reducing the risk of leakage. However, the present disclosure is not limited thereto. In some embodiments, the dielectric layer 204 includes a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), undoped silicate glass (USG), or the like, or a combination thereof. It should be understood that all possible materials for the dielectric layer 204 are included within the scope of the present disclosure. In some embodiments, the dielectric layer 204 is formed, for example, by spin coating, lamination, chemical vapor deposition (CVD), or the like.

Next, as shown in FIG. 1D, a plurality of conductive features 205 are formed on the dielectric layer 204. In some embodiments, the conductive features 205 include conductive material and extend on the dielectric layer 204. The conductive features 205 may include a plurality of vias extending into the dielectric layer 204 and therefore be electrically and physically connected to the conductive features 203. As a result, an electrical connection may be formed between the conductive features 203 and 205.

Then, as shown in FIG. 1E, another dielectric layer 204 is formed over the conductive features 205 for proper insulation. It should be noted that although the dielectric layer 204 is shown as single-layered structure, the dielectric layer 204 may include multiple layers and will not be discussed in detail below. In some embodiments, a plurality of contact pads 207 are formed over the dielectric layer 204 for external electrical connection. That is, the contact pads 207 are electrically connected to the conductive features 203 and 205. Similarly, a dielectric layer 206 is formed over the conductive features 203 and on the lower side of the insulating core 202. It should be understood that the material of the dielectric layer 206 may be the same as or different from the material of the dielectric layer 204, and all possible materials for the dielectric layer 206 are included within the scope of the present disclosure. In addition, a plurality of conductive features 208 are formed in the dielectric layer 206. For example, the formation of the conductive features 208 may be the same as the formation of the conductive features 205, and therefore will not be repeated in the present disclosure for the sake of brevity. In some embodiments, the contact pads 209 are formed over the dielectric layer 206 for external electrical connection. That is, the contact pads 209 are electrically connected to the conductive features 203 and 208. Accordingly, a substrate 200 is formed.

In some embodiments, a first surface 200A and a second surface 200B are defined as opposite surfaces of the substrate 200. For example, the first surface 200A may be the upper surface of the insulating core 202, and the second surface 200B may be the lower surface of the insulating core 202. However, the present disclosure is not limited thereto. In some embodiments, the first surface 200A may be referred to as any surface on the upper side of the insulating layer and parallel to the X-Y plane, and the second surface 200B may be referred to as any surface on the lower side of the insulating layer and parallel to the X-Y plane.

Next, as shown in FIG. 1F, a first photoresist layer 211 is formed over the dielectric layer 204 and the contact pads 207. In some embodiments, the first photoresist layer 211 includes a plurality of openings 213, each of which exposes an underlying contact pad 207. Accordingly, the first photoresist layer 211 may be referred to as “the first patterned photoresist layer 211” at this stage. In some embodiments, the width of the openings 213 may be less than the width of the underlying contact pad 207. That is, the contact pad 207 may be partially exposed from the first photoresist layer 211. In addition, a second photoresist layer 212 is formed over the dielectric layer 206 and the contact pads 209. While the openings 213 are formed in the first photoresist layer 211, no opening exists in the second photoresist layer 212. Therefore, the second photoresist layer 212 completely covers the contact pads 209 at this stage.

Next, as shown in FIG. 1G, a plurality of first metallic features 221 are formed in the openings 213 and on the contact pads 207. The first metallic features 221 are formed to be a portion of connector structures 220, referring to FIG. 1P, for example. As an example to form the first metallic features 221, a seed layer is formed in the openings 213. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the first metallic features 221. For example, the material of first metallic features 221 may be the same as the material of the conductive features 203, 205, and the contact pads 207. However, the present disclosure is not limited thereto.

It should be noted that forming the first metallic features 221 as a portion of the connector structures 220 may narrow down the pitch among the connector structures 220 without degrading the reliability of the package structure. For example, the pitch among the connector structures 220 may be less than about 90 μm, such as about 85 μm, about 80 μm, about 75 μm, etc. Such fine pitch among the connector structures 220 may help to increase the integrated density of the package structure.

Next, as shown in FIG. 1H, after the first metallic features 221 are formed on the contact pads 207, the first metallic features 221 are covered by the first photoresist layer 211. To be more specific, the openings 213 are filled with the first photoresist layer 211 so that the first metallic features 221 may be prevented from the subsequent process. At this stage, the second photoresist layer 212 is etched to include plurality of openings 214, each of which exposes a corresponding contact pad 209. Accordingly, the second photoresist layer 212 may be referred to as “the second patterned photoresist layer 212” at this stage. In some embodiments, the width of the openings 214 may be less than the width of the corresponding contact pad 209. That is, the contact pad 209 may be partially exposed from the second photoresist layer 212. In addition, while the openings 214 are formed in the second photoresist layer 212, no opening exists in the first photoresist layer 211.

Next, as shown in FIG. 1I, a plurality of metallic features 231 are formed in the openings 214 and on the contact pads 209. In some embodiments, the metallic features 231 may be formed by plating or any other suitable method. For example, the material of metallic features 231 may be the same as the material of the conductive features 203, 208, and the contact pads 209. However, the present disclosure is not limited thereto. For example, the material of the metallic features 231 includes copper (Cu) or any other suitable material. In some embodiments, the metallic features 231 may also be referred to as “the second connector structures 231.”

Next, as shown in FIG. 1J, the first photoresist layer 211 and the second photoresist layer 212 are removed to expose the interior of the substrate 200. In some embodiments, the first photoresist layer 211 and the second photoresist layer 212 are stripped from the substrate 200 using a chemical stripper. In some embodiments, the seed layer for forming the first metallic features 221 and 231 may be etched at this stage. However, the present disclosure is not limited thereto.

Next, as shown in FIG. 1K, a first solder mask layer 241 is formed over the first surface 200A of the substrate 200. In some embodiments, the first solder mask layer 241 is formed to cover the contact pads 207 and the first metallic features 221. Similarly, a second solder mask layer 242 is formed over the second surface 200B of the substrate 200. In some embodiments, the second solder mask layer 242 is formed to cover the contact pads 209 and the metallic features 231. In some embodiments, the first solder mask layer 241 and the second solder mask layer 242 are used to protect areas of the substrate 200 from external damage.

Next, as shown in FIG. 1L, the first solder mask layer 241 is thinned down to expose the first metallic features 221. In some embodiments, the top surface of the first solder mask layer 241 may be lower than the top surface of the first metallic features 221. As a result, subsequent processes may be performed to the first metallic features 221 for forming a plurality of connector structures 220.

Next, as shown in FIG. 1M, the second solder mask layer 242 is thinned down to expose the metallic features 231. In some embodiments, the bottom surface of the second solder mask layer 242 may be higher than the bottom surface of the metallic features 231. As a result, subsequent processes may be performed to the metallic features 231 for forming a plurality of connector structures.

Next, as shown in FIG. 1N, a recess 244 may be selectively formed in the second solder mask layer 242 for disposing a package component. In some embodiments, the recess 244 exposes the contact pads 209 and the dielectric layer 206. It should be noted that the size (for example, width) and the location of the recess 244 depend upon the package component to be positioned, and are not limited in the present disclosure.

Next, as shown in FIG. 1O, a surface treatment process is performed to the first metallic features 221, and therefore a second metallic feature 222 is formed around each of the first metallic features 221. The surface treatment process may protect the first metallic features 221 from oxidation and widen the first connector structures 220 over the solder mask layer. In some embodiments, the first connector structures 220 may include the first metallic feature 221 and the second metallic feature 222. The material of the second metallic feature 222 is different from the material of the first metallic feature 221. For example, the surface treatment process may include electroless nickel-electroless palladium-immersion gold (ENEPIG) process. Accordingly, the performance or reliability of the package structure may be enhanced.

Next, as shown in FIG. 1P, a plurality of first package components 250 are bonded to the contact pads 207 via the first connector structures 220. In some embodiments, the first package components 250 include a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

In some embodiments, the first package components 250 are formed in a wafer, which may include different device regions that are singulated in subsequent steps to form a plurality of integrated circuit dies. In some embodiments, the first package components 250 are processed according to applicable manufacturing processes to form integrated circuits. For example, the first package components 250 include a semiconductor substrate, such as silicon, doped or undoped, or an active layer of a semiconductor-on-insulator (SOI) substrate. In some embodiments, the semiconductor substrate includes other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the first package components 250 are stacked devices that includes multiple semiconductor substrates. For example, the first package components 250 may be a memory device such as a hybrid memory cube (HMC) module, a high bandwidth memory (HBM) module, or the like that includes multiple memory dies.

In the embodiment shown, multiple first package components 250 are adhered adjacent one another. For example, one of the first package components 250 may be a logic device, such as a central processing unit (CPU), a graphics processing unit (GPU), a system-on-a-chip (SoC), a microcontroller, or the like. The other first package components 250 may be a memory device, such as a dynamic random access memory (DRAM) die, a static random access memory (SRAM) die, a hybrid memory cube (HMC) module, a high bandwidth memory (HBM) module, or the like. In some embodiments, the first package components 250 are the same type of dies, such as SoC dies. In some embodiments, the integrated circuit dies 50 are formed in the processes of the same technology node, or they are formed in the processes of different technology nodes. For example, one of the first package components 250 may be of a more advanced process node than the other of the first package components 250. The first package components 250 may be different sizes (e.g., different heights and/or surface areas), or they may be the same size (e.g., the same height and/or surface area).

Similarly, a second package component 270 is bonded to the contact pads 209 in the recess 244 of the solder mask layer 242. In some embodiments, the second package component 270 may be the same as or different from either of the first package components 250. In some embodiments, the first connector structures 220 include a dummy connector structure 225 that is disposed between the adjacent first package components 250. In some embodiments, the dummy connector structure 225 is electrically isolated from the first package components 250. In some embodiments, the dummy connector structure 225 protrudes from an upper surface of the first solder mask layer 241. As a result, the dummy connector structure 225 may serve as a barrier for positioning the first package components 250. In some embodiments, the height of the dummy connector structure 225 may be greater than about 3 μm so as to block the molding material 150. To be more specific, the arrangement of the dummy connector structure 225 may help to confine the molding material 150 within a given region, reducing the risk that the molding material 150 overflows to undesired regions. For example, the height of the dummy connector structure 225 may be measured from the upper surface of the first solder mask layer 214 in the normal direction of the substrate 200. However, the present disclosure is not limited thereto.

Next, as shown in FIG. 1Q, an underfill 280 is formed between the first package components 250 and the first solder mask layer 241, including between and around the first connector structures 220. In some embodiments, the underfill 280 is formed by a capillary flow process after the first package components 250 are attached or is formed by a suitable deposition method before the first package components 250 are attached. In some embodiments, the underfill 280 is also between the first package components 250. Similarly, the underfill 280 is formed between the second package component 270 and the second solder mask layer 242.

In some embodiments, a molding material 290 is formed around the first package components 250, the first connector structures 220, and the underfill 280. After formation, the molding material 290 encapsulates the first connector structures 220 and the first package components 250. In some embodiments, the molding material 290 is a molding compound, epoxy, or the like. In some embodiments, the molding material 290 is applied by compression molding, transfer molding, or the like. In some embodiments, the molding material 290 is applied in liquid or semi-liquid form and then subsequently cured. In some embodiments, a planarization step may be performed to remove and planarize an upper surface of the molding material 290. Similarly, the molding material 290 is formed around the second package component 270 and the underfill 280.

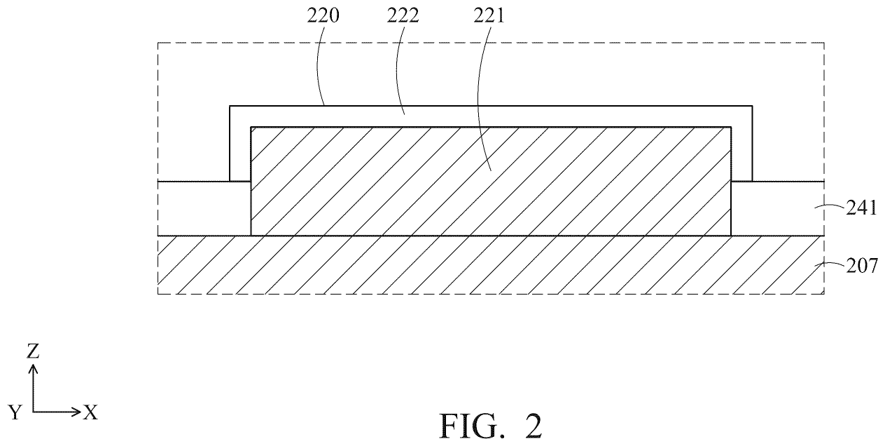

FIG. 2 illustrates a partial enlarged view of the package structure 10 in accordance with some embodiments. For example, FIG. 2 may be illustrated in the region A shown in FIG. 1O. However, the present disclosure is not limited thereto. As shown in FIG. 2, the first connector structure 220 includes the first metallic feature 221 and the second metallic feature 222. In some embodiments, the second metallic feature 222 is located above the first solder mask layer 241. In some embodiments, the diameter of the first connector structure 220 may be not less than about 26 μm. In particular, the diameter of the first metallic feature 221 may be substantially equal to about 20 μm, and the overall width of the second metallic feature 222 may be substantially equal to about 6 μm. However, the present disclosure is not limited thereto. Accordingly, the risk that oxidation occurs to the first connector structure 220 may be reduced, and therefore the performance or reliability of the package structure 10 may be enhanced. It should be noted that the sidewall of the first connector structure 220 may be vertical, that is for example, parallel to the normal direction (such as the Z direction) of the substrate 200. Accordingly, the stress of the connector structures may be relieved, providing a larger process window. In some embodiments, the height of the first connector structure 220 may be greater than about 3 μm. For example, the height of the first connector structure 220 may be measured from the upper surface of the first solder mask layer 214 in the normal direction of the substrate 200. However, the present disclosure is not limited thereto.

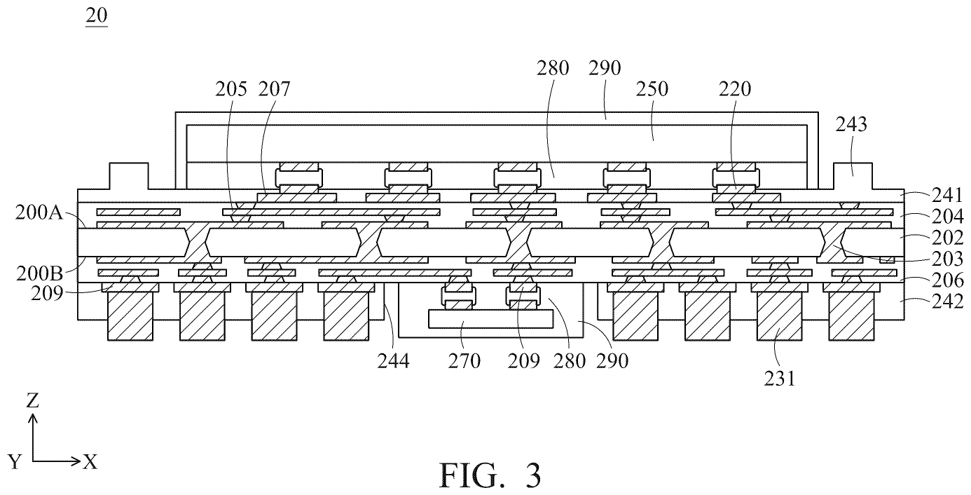

FIG. 3 illustrates a cross-sectional view of the package structure 20 in accordance with some embodiments. It should be noted that the package structure 20 in this embodiment may include the same or similar portions or elements as those of the package structure 10 in FIG. 1. For the sake of brevity, these portions or elements will be denoted as the same or similar numerals, and will not be discussed in detail as follows. For example, the connector structures 220 shown in FIG. 3 include the first metallic features 221 and the second metallic features 222. As shown in FIG. 3, a plurality of spacer portions 243 are formed on the first solder mask layer 241 so as to serve as barrier for positioning the first package component 250. It should be noted that since the first solder mask layer 241 is formed after the first metallic features 221 of the connector structures 220 are formed, the first solder mask layer 241 may be formed as a stepped structure in single process. As a result, the first solder mask layer 241 may be formed seamlessly, or the formation of the first solder mask layer 241 may be simplified. In some embodiments, the connector structures 220 and the first package component 250 are located between and spaced apart from the spacer portions 243. In some embodiments, the molding material 290 is spaced apart from the spacer portions 243. However, the present disclosure is not limited thereto. In some embodiments, the molding material 290 may be in contact with the spacer portions 243. With the arrangement of the spacer portions 243, the molding material 290 may be confined in a preset region.

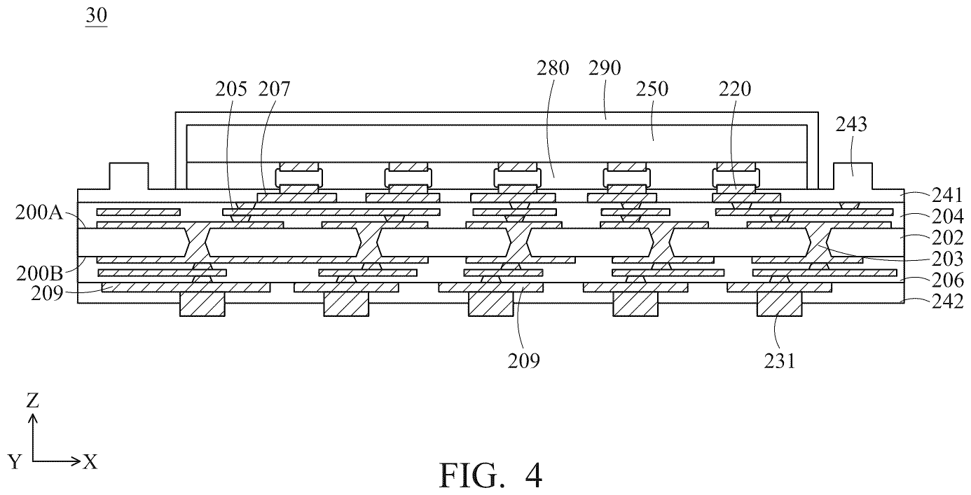

FIG. 4 illustrates a cross-sectional view of the package structure 30 in accordance with some embodiments. It should be noted that the package structure 30 in this embodiment may include the same or similar portions or elements as those of the package structure 10 in FIG. 1. For the sake of brevity, these portions or elements will be denoted as the same or similar numerals, and will not be discussed in detail as follows. For example, the connector structures 220 shown in FIG. 4 include the first metallic features 221 and the second metallic features 222. As shown in FIG. 4, the second package component 270 is omitted. As a result, the process for forming the package structure 30 may be simplified. Accordingly, the process time and cost of the package structure 30 may be saved.

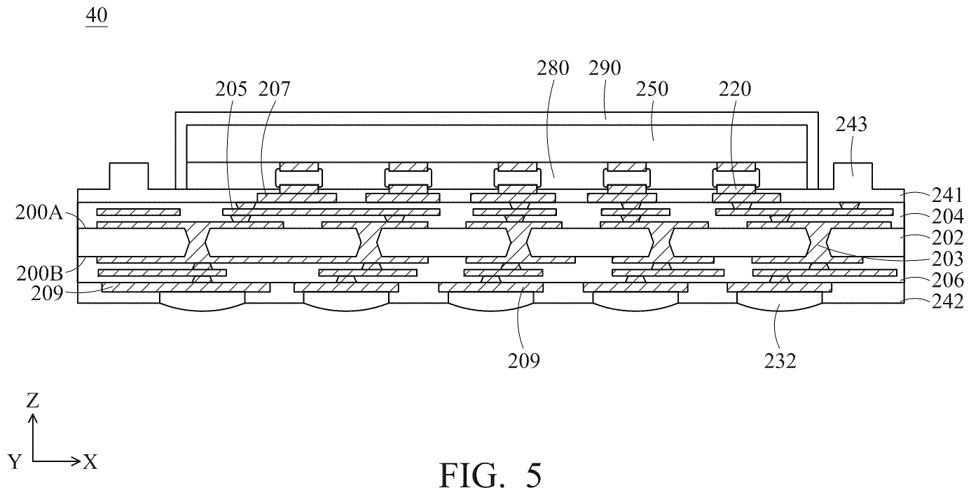

FIG. 5 illustrates a cross-sectional view of the package structure 40 in accordance with some embodiments. It should be noted that the package structure in this embodiment may include the same or similar portions or elements as those of the package structure 10 in FIG. 1. For the sake of brevity, these portions or elements will be denoted as the same or similar numerals, and will not be discussed in detail as follows. For example, the connector structures 220 shown in FIG. 5 include the first metallic features 221 and the second metallic features 222. As shown in FIG. 5, the conductive connectors 232 are formed on the contact pads 209. The conductive connectors 232 may be ball grid array (BGA) connectors, solder balls, controlled collapse chip connection (C4) bumps, micro bumps, electroless nickel-electroless palladium-immersion gold technique (ENEPIG) formed bumps, or the like. In some embodiments, the conductive connectors 232 include a conductive material such as solder, copper, aluminum, gold, nickel, silver, palladium, tin, the like, or a combination thereof. In some embodiments, the conductive connectors 232 are formed by initially forming a layer of solder through evaporation, electroplating, printing, solder transfer, ball placement, or the like. Once a layer of solder has been formed on the structure, a reflow may be performed in order to shape the material into the desired bump shapes. By replacing the metallic features 231 with the conductive connectors 232, the process for forming the package structure 40 may be simplified, thereby saving the process time and cost of the package structure 40.

Embodiments of package structures and method for fabricating the same are provided. The package structure includes a plurality of connector structure exposed from the solder mask layer. In some embodiments, the connector structure are formed, for example, by metallic features. As a result, the pitch between the connector structures may be narrowed down without degrading the reliability of the package structure. The fine pitch may help to increase the integrated density of the package structure. In addition, the sidewall of the connector structures may be vertical, that is for example, parallel to the normal direction of the substrate. Accordingly, the stress of the connector structures may be relieved, providing a larger process window. Furthermore, the connector structures may include a dummy connector structure which serve as a barrier for positioning the package components, thereby increasing the yield of the package structure. Also, the package components may be bonded to the opposite surfaces of the substrate, and therefore the integrated density of the package structure may be increased, improving the performance of the package structure.

In some embodiments, a method for fabricating a package structure is provided. The method includes forming a first patterned photoresist layer over a first surface of a substrate. The method includes forming a plurality of first connector structures in openings of the first patterned photoresist layer. The method includes removing the first patterned photoresist layer. The method includes forming a solder mask layer over the first connector structures. The method includes performing a surface treatment process to the first connector structures. The method also includes bonding a package component to the substrate via the first connector structures.

In some embodiments, a package structure is provided. The package structure includes a substrate having a first surface and a second surface opposite to the first surface. The package structure includes a first solder mask layer over the first surface of the substrate. The package structure includes a plurality of first connector structures formed over the first surface. The connector structures includes a dummy connector structure formed laterally between and electrically isolated from adjacent two of the plurality of connector structures. The package structure includes a first package component bonded to the substrate via the plurality of connector structures. The package structure also includes a molding material over the first solder mask layer and encapsulating the connector structures and the first package component.

In some embodiments, a package structure is provided. The package structure includes a substrate comprising a plurality of dielectrics layers and a plurality of conductive patterns in the plurality of dielectrics layers. The package structure includes a solder mask layer over the substrate. The solder mask layer includes a plurality of spacer portions vertically protruding from the top surface of the solder mask layer. The package structure includes a plurality of connector structures formed over the substrate and protruding from the top surface of the solder mask layer. The connector structures are located between the spacer portions, the connector structures each include a first metallic feature and a second metallic feature around the first metallic feature, and a material of the first metallic feature is different from a material of the second metallic feature. The package structure includes a package component bonded to the conductive patterns of the substrate via the connector structures, and located laterally between the spacer portions. The package structure also includes a molding material encapsulating the package component and the connector structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a package structure, comprising:
forming a first patterned photoresist layer over a first surface of a substrate;
forming a plurality of first connector structures in openings of the first patterned photoresist layer;
removing the first patterned photoresist layer;
forming a solder mask layer over the first connector structures;
performing a surface treatment process to the first connector structures; and
bonding a package component to the substrate via the first connector structures.

2. The method as claimed in claim 1, further comprising:
forming a second patterned photoresist layer over a second surface of the substrate, wherein the second surface is opposite to the first surface; and
forming a plurality of second connector structures in openings of the second patterned photoresist layer.

3. The method as claimed in claim 1, wherein forming the solder mask layer over the first connector structures comprises exposing the first connector structures form a top surface of the solder mask layer.

4. The method as claimed in claim 1, wherein forming the solder mask layer over the first connector structures comprises forming a spacer portion of the solder mask layer protruding over the first connector structures.

5. The method as claimed in claim 1, wherein the first connector structures comprises a dummy connector structure exposed from the package component.

6. The method as claimed in claim 1, wherein performing the surface treatment process to the first connector structures comprises widening the first connector structures over the solder mask layer.

7. The method as claimed in claim 1, wherein a sidewall of the plurality of connector structures is substantially parallel to a normal direction of the substrate.

8. A package structure, comprising:
a substrate having a first surface and a second surface opposite to the first surface;
a first solder mask layer over the first surface of the substrate;
a plurality of first connector structures formed over the first surface, wherein the first connector structures comprises a dummy connector structure disposed laterally between and electrically isolated from adjacent two of the plurality of first connector structures;
a first package component bonded to the substrate via the plurality of first connector structures; and
a molding material over the first solder mask layer and encapsulating the first connector structures and the first package component.

9. The package structure as claimed in claim 8, further comprising:
a second solder mask layer over the second surface of the substrate; and
a second package component bonded to the substrate and disposed in a recess of the second solder mask layer.

10. The package structure as claimed in claim 9, further comprising:
a plurality of second connector structures formed over the second surface, wherein the second connector structures protrude from the second solder mask layer and have sidewalls substantially parallel to a normal direction of the substrate.

11. The package structure as claimed in claim 8, further comprising:
an underfill encapsulating the first connector structures and located between the first package component and the substrate.

12. The package structure as claimed in claim 8, wherein the dummy connector structure protrudes from an upper surface of the first solder mask layer.

13. The package structure as claimed in claim 8, wherein a spacer portion is formed on the first solder mask layer, and the first package component is spaced apart from the spacer portion

14. The package structure as claimed in claim 13, wherein the molding material is spaced apart from spacer portion.

15. A package structure, comprising:
a substrate comprising a plurality of dielectrics layers and a plurality of conductive patterns in the plurality of dielectrics layers;
a solder mask layer over the substrate, wherein the solder mask layer comprises a plurality of spacer portions vertically protruding from a top surface of the solder mask layer;
a plurality of connector structures formed over the substrate and protruding from the top surface of the solder mask layer, wherein the connector structures are located between the spacer portions, the connector structures each comprise a first metallic feature and a second metallic feature around the first metallic feature, and a material of the first metallic feature is different from a material of the second metallic feature;
a package component bonded to the conductive patterns of the substrate via the connector structures, and located laterally between the spacer portions; and
a molding material encapsulating the package component and the connector structures.

16. The package structure as claimed in claim 15, wherein a top surface of the spacer portions are higher than a top surface of the connector structures.

17. The package structure as claimed in claim 15, wherein the molding material is in contact with the spacer portions.

18. The package structure as claimed in claim 15, wherein the connector structures are spaced apart from the spacer portions via the molding material.

19. The package structure as claimed in claim 15, wherein a material of the connector structures is the same as a material of the conductive patterns.

20. The package structure as claimed in claim 15, wherein a sidewall of the plurality of connector structures is substantially parallel to a normal direction of the substrate.
